(19) United States
(12) Patent Application Publication
(10) Pub. No.: US 2025/0095732 A1
(43) Pub. Date: Mar. 20, 2025

(54) MEMORY DEVICE AND INITIALIZING METHOD THEREOF

(71) Applicant: SAMSUNG ELECTRONICS CO., LTD., SUWON-SI (KR)

(72) Inventors: KYUDONG PARK, Suwon-si (KR); SEULJI SONG, Suwon-si (KR); KWANG-WOO LEE, Suwon-si (KR)

(21) Appl. No.: 18/624,884

(22) Filed: Apr. 2, 2024

(30) Foreign Application Priority Data
Sep. 19, 2023 (KR) 10-2023-0125100

(51) Int. Cl. G11C 13/00

(52) U.S. Cl. CPC G11C 13/0069; G11C 13/0026; G11C 13/0028; G11C 13/004; G11C 2013/0083

(57) ABSTRACT

A memory device includes word lines, bit lines, memory cells, and a circuit. The circuit applies a first voltage to a first bit line of a target memory cell, applies a second voltage to a first word line of the target memory cell, and performs at least one of a first operation and a second operation. The first operation includes applying an adjustment voltage to a second bit line or second word line connected to an adjacent initialized memory cell, and the second operation includes applying a third voltage of an opposite polarity to the first voltage to a third bit line of a next target memory cell that is initialized after initialization of the target memory cell and applying a fourth voltage of an opposite polarity to the second voltage to a third word line of the next target memory cell.

### CROSS-REFERENCE TO RELATED APPLICATION

This application claims priority under 35 U.S.C. § 119 to Korean Patent Application No. 10-2023-0125100, filed on Sep. 19, 2023, the disclosure of which is incorporated by reference herein in its entirety.

### TECHNICAL FIELD

Embodiments of the present disclosure relate to a memory device and an initialization method of the memory device.

### DISCUSSION OF RELATED ART

A selector only memory (SOM) based on a Chalcogenide (Ch) class has a simple structure by combining memory and switch characteristics into one material, making it efficient to develop as a highly integrated storage memory. In addition, because the SOM has a low operating current and fast operating speed, the driving power of the SOM is less than that of existing phase change memory (PcRAM). Because the SOM does not include a separate selection device, leakage current for normal read and write operations should be reduced or minimized.

A SOM device has a higher threshold voltage compared to an operating voltage of a memory device immediately after fab-out. An initialization operation is utilized to change the threshold voltage of the SOM device to be within an operating voltage range of the memory device. However, the leakage current of the SOM device on which the initialization operation is performed increases, and other SOM devices on which the initialization operation is performed at a lower priority may fail to initialize due to the leakage current.

### SUMMARY

Embodiments of the present disclosure provide a memory device capable of preventing an initialization operation failure of a memory cell such as a selector only memory (SOM) device, and an initialization method of the memory device.

According to an aspect of the disclosure, a memory device includes a plurality of word lines extending in a first direction, a plurality of bit lines extending in a second direction crossing the first direction, a plurality of memory cells disposed in a plurality of areas in which the plurality of word lines and the plurality of bit lines intersect, and a circuit configured to apply a first voltage to a first bit line of a target memory cell, which is an initialization target cell among the plurality of memory cells, apply a second voltage to a first word line of the target memory cell, and perform at least one of a first operation and a second operation. The plurality of bit lines includes the first bit line, and the plurality of word lines includes the first word line. The first operation includes applying an adjustment voltage to a second bit line or a second word line connected to an adjacent initialized memory cell that is an initialized memory cell among adjacent initialization cells that share the first bit line or the first word line. The second operation includes applying a third voltage of an opposite polarity to the first voltage to a third bit line of a next target memory cell that is initialized after initialization of the target memory cell, and applying a fourth voltage of an opposite polarity to the second voltage to a third word line of the next target memory cell. The plurality of bit lines includes the second bit line and the third bit line, and the plurality of word lines includes the second word line and the third word line.

According to an aspect of the disclosure, an initializing method of a memory device including a plurality of word lines, a plurality of bit lines, and a plurality of memory cells disposed in a plurality of areas in which the plurality of word lines and the plurality of bit lines intersect includes applying a first voltage to a first bit line of a target memory cell, which is an initialization target cell among the plurality of memory cells, and applying a second voltage to a first word line of the target memory cell, and applying an adjustment voltage to a second bit line or a second word line connected to an adjacent initialized memory cell that is an initialized memory cell among adjacent initialization cells that share the first bit line or the first word line. The plurality of bit lines includes the first and second bit lines, and the plurality of word lines includes the first and second word lines.

According to an aspect of the disclosure, an initializing method of a memory device including a plurality of word lines, a plurality of bit lines, and a plurality of memory cells disposed in a plurality of areas in which the plurality of word lines and the plurality of bit lines intersect includes applying a first voltage to a first bit line of a target memory cell, which is an initialization target cell among the plurality of memory cells, and applying a second voltage to a first word line of the target memory cell, and applying a third voltage of an opposite polarity to the first voltage to a second bit line of a next target memory cell that is initialized after initialization of the target memory cell, and applying a fourth voltage of an opposite polarity to the second voltage to a second word line of the next target memory cell. The plurality of bit lines includes the first and second bit lines, and the plurality of word lines includes the first and second word lines.

### BRIEF DESCRIPTION OF THE DRAWINGS

The above and other features of the present disclosure will become more apparent by describing in detail embodiments thereof with reference to the accompanying drawings.

FIG. 1 is a three-dimensional perspective view illustrating a memory device according to an embodiment.

FIG. 2 is a diagram illustrating a memory cell and corresponding word line and bit line connected thereto in a first memory layer according to an embodiment.

FIG. 3 is a diagram illustrating a memory cell and corresponding word line and bit line connected thereto in a second memory layer according to an embodiment.

FIG. 4 is a diagram illustrating a memory cell and corresponding word line and bit line connected thereto in a third memory layer according to an embodiment.

FIG. 5 is a diagram illustrating a memory cell and corresponding word line and bit line connected thereto in a fourth memory layer according to an embodiment.

FIG. 6 is a diagram schematically illustrating a plurality of memory cells disposed in areas in which word lines and bit lines intersect according to an embodiment.

FIG. 7 is a diagram schematically illustrating a plurality of memory cells disposed in areas in which word lines and bit lines intersect according to an embodiment.

FIG. 8 is a diagram schematically illustrating a plurality of memory cells disposed in areas in which word lines and bit lines intersect according to an embodiment.

FIG. 9 is a diagram schematically illustrating a plurality of memory cells disposed in areas in which word lines and bit lines intersect according to an embodiment.

FIG. 10 is a diagram schematically illustrating a plurality of memory cells disposed in areas in which word lines and bit lines intersect according to an embodiment.

FIG. 11 is a diagram schematically illustrating a plurality of memory cells disposed in areas in which word lines and bit lines intersect according to an embodiment.

FIG. 12 is a diagram schematically illustrating a plurality of memory cells disposed in areas in which word lines and bit lines intersect according to an embodiment.

FIG. 13 is a diagram schematically illustrating a plurality of memory cells disposed in areas in which word lines and bit lines intersect according to an embodiment.

FIG. 14 is a diagram schematically illustrating a plurality of memory cells disposed in areas in which word lines and bit lines intersect according to an embodiment.

FIG. 15 is a diagram schematically illustrating a plurality of memory cells and a plurality of word lines connected to a bit line for describing an embodiment.

FIG. 16 is a waveform diagram illustrating voltage waveforms supplied to a bit line and a plurality of word lines during an initialization operation according to an initialization progress direction shown in FIG. 15.

FIG. 17 is a curved graph illustrating voltage-current characteristics in a positive polarity write and voltage-current characteristics in a negative polarity write with respect to a selector only memory (SOM) device.

FIG. 18 is a diagram schematically illustrating that positive/negative polarity initialization operations are performed according to an initialization progress direction during an initialization operation in a multi-deck structure according to an embodiment.

FIG. 19 is a diagram schematically illustrating that positive/negative polarity initialization operations are performed according to an initialization progress direction during an initialization operation in a multi-deck structure according to an embodiment.

FIG. 20 is a waveform diagram illustrating waveforms of a bit line voltage and a word line voltage for a positive polarity initialization operation or a negative polarity initialization operation supplied to a bit line and a plurality of word lines according to an embodiment.

FIG. 21 is a waveform diagram illustrating waveforms of a bit line voltage and a word line voltage for a positive polarity initialization operation or a negative polarity initialization operation supplied to a bit line and a plurality of word lines according to an embodiment.

FIG. 22 is a waveform diagram illustrating waveforms of a bit line voltage and a word line voltage for a positive polarity initialization operation or a negative polarity initialization operation supplied to a bit line and a plurality of word lines according to an embodiment.

FIG. 23 is a diagram schematically showing a plurality of memory cells disposed in areas in which word lines and bit lines intersect according to an embodiment.

FIG. 24 is a diagram schematically showing a plurality of memory cells disposed in areas in which word lines and bit lines intersect according to an embodiment.

FIG. 25 is a block diagram illustrating a semiconductor device according to an embodiment.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

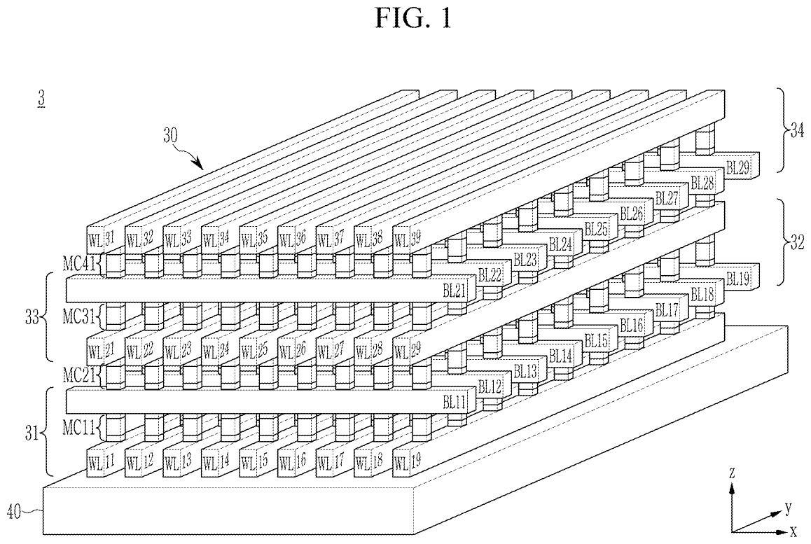

FIG. 1 is a three-dimensional perspective view illustrating a memory device 3 according to an embodiment.

The memory device 3 may include a memory cell array 30 and a peripheral circuit 40.

The memory device 3 shown in FIG. 1 may be a memory device disposed on a wafer, or may be separate from the wafer and combined with other components to implement a semiconductor device. FIG. 1 shows that the memory device 3 includes the peripheral circuit 40. However, embodiments are not limited thereto. For example, according to embodiments, when the memory device 3 disposed on the wafer, the memory device 3 may not include the peripheral circuit 40.

FIG. 1 shows a memory cell array 30 of a multi-deck structure. FIG. 1 shows that the memory cell array 30 includes first to fourth memory layers 31 to 34, but the number of memory layers constituting the memory cell array 30 is not limited thereto. The structure of the memory cell array 30 shown in FIG. 1 is an example provided for describing embodiments of the disclosure, and the disclosure is not limited thereto.

The memory cell array 30 may include a plurality of memory cells respectively disposed in areas in which a plurality of first signal lines and a plurality of second signal lines intersect. In an embodiment, the first signal line may be one of a bit line and a word line, and the second signal line may be the other of the bit line and the word line. Each of the plurality of memory cells may be a single level cell that stores one bit of data, or a multi-level cell that stores at least 2 or more bits of data. In addition, the memory cells may have a plurality of resistance distributions according to the number of bits stored in each memory cell. For example, when 1 bit of data is stored in each memory cell, the memory cells may have two resistance distributions, and when 2 bits of data are stored in each memory cell, the memory cells may have four resistance distributions.

Each of the plurality of memory cells may be a resistive memory cell including a variable resistance device. For example, in an embodiment, when the variable resistance device includes a phase change material, and the resistance changes with temperature, a resistive memory device may be a phase-change random access memory (PRAM). For example, in an embodiment, when the variable resistance device is formed as an upper electrode, a lower electrode, and a transition complex metal oxide disposed therebetween, the resistive memory device may be a resistive random access memory (RRAM). For example, in an embodiment, when the variable resistance device is formed as an upper electrode of a magnetic material, a lower electrode of a magnetic material, and a dielectric material disposed therebetween, the resistive memory device may be a magnetoresistive random access memory (MRAM). The memory cell in some embodiments of the present disclosure may be implemented as the resistive memory cell.

The peripheral circuit 40 may be electrically connected to the memory cell array 30 and disposed on one side of the memory cell array 30. For example, FIG. 1 shows that the first to fourth memory layers 31 to 34 are sequentially formed and disposed on an upper portion of the peripheral circuit 40. The peripheral circuit 40 may include a plurality of wirings connected to a plurality of bit lines BL11 to BL19 and BL21 to BL29, and a plurality of wirings connected to a plurality of word lines WL11 to WL19, WL21 to WL29, and WL31 to WL39. A voltage may be applied to each of the plurality of bit lines BL11 to BL19 and BL21 to BL29 and the plurality of word lines WL11 to WL19, WL21 to WL29, and WL31 to WL39 through the plurality of wirings of the peripheral circuit 40. In the following description, it may be understood that the voltages are supplied to the plurality of bit lines BL11 to BL19 and BL21 to BL29 and the plurality of word lines WL11 to WL19, WL21 to WL29, and WL31 to WL39 through the peripheral circuit 40. Thus, voltages applied, and operations performed, may be applied and performed by the peripheral circuit 40. However, the disclosure is not limited thereto. For example, in an embodiment, a separate initialization driving circuit is provided instead of the peripheral circuit 40, and may supply voltages utilized for an initialization operation to the plurality of bit lines BL11 to BL19 and BL21 to BL29 and the plurality of word lines WL11 to WL19, WL21 to WL29, and WL31 to WL39. Thus, voltages applied, and operations performed, may be applied and performed by the separate initialization driving circuit.

The memory cell array 30 may include the first to fourth memory layers 31 to 34, and two adjacent memory layers among the first to fourth memory layers 31 to 34 may share the plurality of bit lines BL11 to BL19 and BL21 to BL29 or the plurality of word lines WL11 to WL19, WL21 to WL29, and WL31 to WL39.

The plurality of bit lines BL11 to BL19 and BL21 to BL29 may extend in a first direction (x-axis direction). The plurality of bit lines BL11 to BL19 may be arranged in a second direction (y-axis direction) to be shared by the first memory layer 31 and the second memory layer 32. The plurality of bit lines BL21 to BL29 may be arranged in the second direction to be shared by the third memory layer 33 and the fourth memory layer 34.

The plurality of word lines WL11 to WL19, WL21 to WL29, and WL31 to WL39 may extend in the second direction. The plurality of word lines WL11 to WL19 may be disposed on the upper portion of the peripheral circuit 40 and may be arranged in the first direction. The plurality of word lines WL21 to WL29 may be arranged in the first direction to be shared by the second memory layer 32 and the third memory layer 33. The plurality of word lines WL31 to WL39 may be arranged in the first direction to be shared by the third memory layer 33 and the fourth memory layer 34.

A plurality of memory cells MC11 may be formed and arranged in a third direction (z-axis direction) in a plurality of areas in which the plurality of word lines WL11 to WL19 and the plurality of bit lines BL11 to BL19 intersect. The first memory layer 31 may be implemented with the plurality of word lines WL11 to WL19, the plurality of bit lines BL11 to BL19, and the plurality of memory cells MC11.

A plurality of memory cells MC21 may be formed and arranged in the third direction (z-axis direction) in a plurality of areas in which the plurality of bit lines BL11 to BL19 and the plurality of word lines WL21 to WL29 intersect. The second memory layer 32 may be implemented with the plurality of bit lines BL11 to BL19, the plurality of word lines WL21 to WL29, and the plurality of memory cells MC21.

A plurality of memory cells MC31 may be formed and arranged in the third direction (z-axis direction) in a plurality of areas in which the plurality of word lines WL21 to WL29 and the plurality of bit lines BL21 to BL29 intersect. The third memory layer 33 may be implemented with the plurality of word lines WL21 to WL29, the plurality of bit lines BL21 to BL29, and the plurality of memory cells MC31.

A plurality of memory cells MC41 may be formed and arranged in the third direction (z-axis direction) in a plurality of areas in which the plurality of bit lines BL21 to BL29 and the plurality of word lines WL31 to WL39 intersect. The fourth memory layer 34 may be implemented with the plurality of bit lines BL21 to BL29, the plurality of word lines WL31 to WL39, and the plurality of memory cells MC41.

In the following description, each of the plurality of memory cells may be formed in a structure in which a first electrode, a switch memory, and a second electrode are stacked.

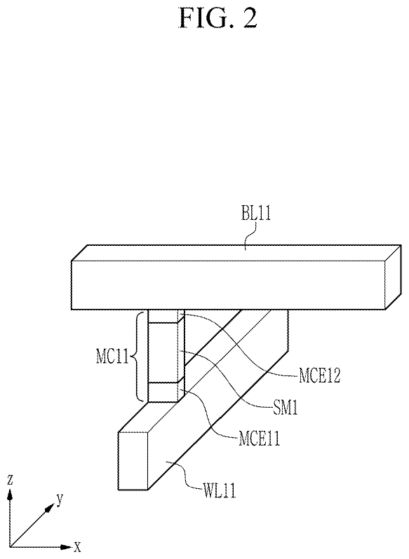

FIG. 2 is a diagram illustrating a memory cell and corresponding word line and bit line connected thereto in a first memory layer according to an embodiment.

For convenience of explanation, FIG. 2 shows the word line WL11, the bit line BL11, and the memory cell MC11 disposed in an intersection area.

The memory cell MC11 may include a first electrode MCE11, a switch memory SM1 stacked on the first electrode MCE11, and a second electrode MCE12 stacked on the switch memory SM1. The first electrode MCE11 may be in contact with the corresponding word line WL11, the second electrode MCE12 may be in contact with the corresponding bit line BL11, and the switch memory SM1 may be disposed between the first electrode MCE1 and the second electrode MCE2. The switch memory SM1 has a structure in which a switching device and a memory device are combined, and may be implemented as an ovonic threshold switch (OTS). The OTS may be manufactured from a chalcogenide material. When a voltage applied to both ends of the switch memory SM1 is lower than a certain threshold, current may not flow in the switch memory SM1, and current may rapidly increase in the switch memory SM1 above a certain reference voltage. Hereinafter, it is described that a memory cell is implemented as the OTS. However, the disclosure is not limited thereto. For example, according to embodiments, the memory cell may be implemented using, for example, an oxide-based switching selection device using a metal-insulator transition phenomenon of oxide.

A plurality of memory cells may be formed and arranged in the third direction (z-axis direction) in a plurality of areas in which the plurality of word lines WL21 to WL29 and the plurality of bit lines BL11 to BL19 intersect. The second memory layer 32 may be implemented with the plurality of word lines WL21 to WL29, the plurality of bit lines BL11 to BL19, and the plurality of memory cells.

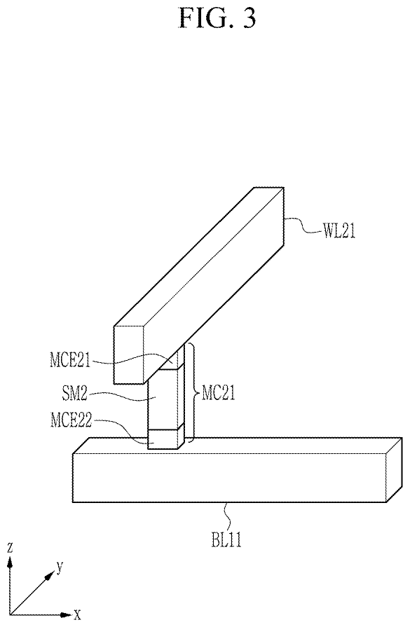

FIG. 3 is a diagram illustrating a memory cell and corresponding word line and bit line connected thereto in a second memory layer according to an embodiment.

For convenience of explanation, FIG. 3 shows the word line WL21, the bit line BL11, and the memory cell MC21 disposed in an intersection area.

The memory cell MC21 may include a second electrode MCE22, a switch memory SM2 stacked on the second electrode MCE22, and a first electrode MCE21 stacked on the switch memory SM2. The first electrode MCE21 may be in contact with the corresponding word line WL21, the second electrode MCE22 may be in contact with the corresponding bit line BL11, and the switch memory SM2 may be disposed between the first electrode MCE21 and the second electrode MCE22.

A plurality of memory cells may be formed and arranged in in the third direction (z-axis direction) in a plurality of areas in which the plurality of word lines WL21 to WL29 and the plurality of bit lines BL21 to BL29 intersect. The third memory layer 33 may be implemented with the plurality of word lines WL21 to WL29, the plurality of bit lines BL21 to BL29, and the plurality of memory cells.

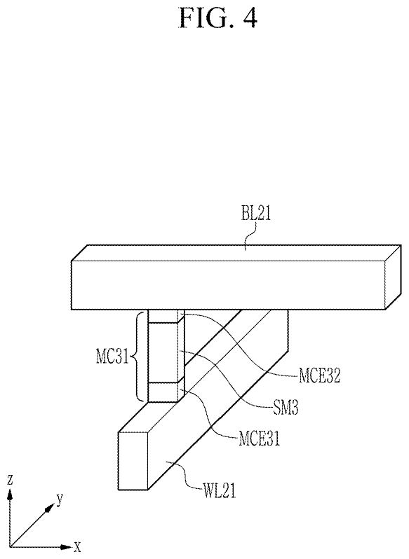

FIG. 4 is a diagram illustrating a memory cell and corresponding word line and bit line connected thereto in a third memory layer according to an embodiment.

For convenience of explanation, FIG. 4 shows the word line WL21, the bit line BL21, and the memory cell MC31 disposed in an intersection area.

The memory cell MC31 may include a first electrode MCE31, a switch memory SM3 stacked on the first electrode MCE31, and a second electrode MCE32 stacked on the switch memory SM3. The first electrode MCE31 may be in contact with the corresponding word line WL21, the second electrode MCE32 may be in contact with the corresponding bit line BL21, and the switch memory SM3 may be disposed between the first electrode MCE31 and the second electrode MCE32.

A plurality of memory cells may be formed and arranged in the third direction (z-axis direction) in a plurality of areas in which the plurality of word lines WL31 to WL39 and the plurality of bit lines BL21 to BL29 intersect. The fourth memory layer 34 may be implemented with the plurality of word lines WL31 to WL39, the plurality of bit lines BL21 to BL29, and the plurality of memory cells.

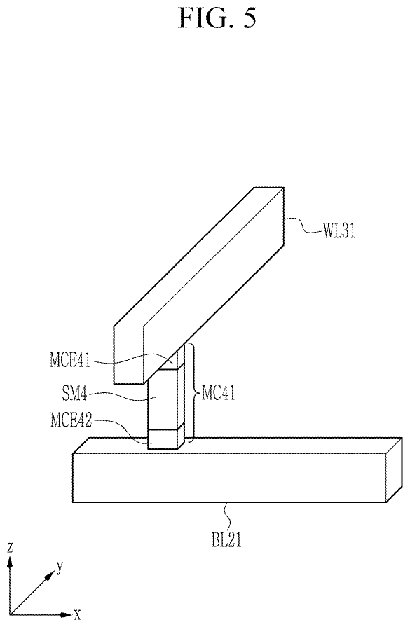

FIG. 5 is a diagram illustrating a memory cell and corresponding word line and bit line connected thereto in a fourth memory layer according to an embodiment.

For convenience of explanation, FIG. 5 shows the word line WL31, the bit line BL21, and the memory cell MC41 disposed in an intersection area.

The memory cell MC41 may include a second electrode MCE42, a switch memory SM4 stacked on the second electrode MCE42, and a first electrode MCE41 stacked on the switch memory SM4. The first electrode MCE41 may be in contact with the corresponding word line WL31, the second electrode MCE42 may be in contact with the corresponding bit line BL21, and the switch memory SM4 may be disposed between the first electrode MCE41 and the second electrode MCE42.

A threshold voltage, which is a reference voltage of an on/off operation of a switch memory according to an embodiment, should fall within an operating voltage range of a memory device. That is, when the switch memory performs a switching operation according to a difference between two voltages provided through a word line and a bit line, the threshold voltage, which is the reference voltage, should fall within the operating voltage range. An operation of driving the switch memory so that the threshold voltage of the switch memory falls within the operating voltage range is referred to as an initialization operation.

The initialization operation on a memory cell array may be performed for each layer in a structure including a plurality of memory layers. In addition, the initialization operation in one memory layer may be performed on each of a plurality of bit lines for each of a plurality of word lines. In this case, a threshold voltage of a memory cell (hereinafter referred to as an initialization memory cell) on which the initialization operation is performed first is lowered, which may cause a problem in which the leakage current of the initialization memory cell increases compared to the leakage current of a memory cell (hereinafter referred to as a non-initialization memory cell) on which the initialization operation is not performed during the initialization operation on the other memory cells. An embodiment in which the leakage current of the initialization memory cell during the initialization operation may be limited is described below.

In the initialization operation according to an embodiment, an adjustment voltage VH may be applied to a second bit line or a second word line connected to an initialized memory cell (hereinafter, referred to as an adjacent initialization cell) among adjacent initialization cells sharing a first bit line or a first word line with a target memory cell that is an initialization target memory cell. The second bit line or the second word line is connected to the adjacent initialization cell and is not connected to the target memory cell.

Hereinafter, it is described that voltages applied to word lines not connected to the target memory cell among a plurality of word lines are all the same, and voltages applied to bit lines not connected to the target memory cell among a plurality of bit lines are all the same.

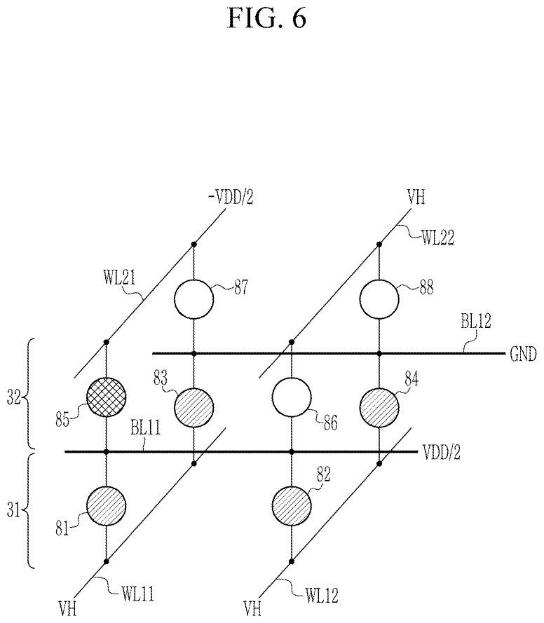

FIG. 6 is a diagram schematically illustrating a plurality of memory cells disposed in areas in which word lines and bit lines intersect according to an embodiment.

For convenience of explanation, FIG. 6 shows eight memory cells 81 to 88 connected to the two bit lines BL11 and BL12 and the four word lines WL11, WL12, WL21, and WL22 among a plurality of bit lines and a plurality of word lines connected to the first memory layer 31 and the second memory layer 32.

In FIG. 6, the plurality of memory cells 81 to 84 disposed in the first memory layer 31 are initialized cells (marked with slashes in the drawing). That is, the threshold voltage of the plurality of memory cells 81 to 84 is lowered to a level suitable for a memory operation. Following initialization on the first memory layer 31, an initialization operation may be performed on the memory cell 85, which is a target memory cell (marked with a checkered pattern in the drawing) disposed in the second memory layer 32. In the initialization operation performed on the memory cell 85, a positive polarity voltage VDD/2 may be applied to the bit line BL11, and a negative polarity voltage −VDD/2 may be applied to the word line WL21. The adjustment voltage VH may be applied to a plurality of word lines (e.g., WL11 and WL12) connected to adjacent initialization cells (e.g., 81 and 82) that share the bit line BL11 with the memory cell 85. One voltage may be applied to a plurality of word lines that are not connected to the target memory cell 85. In an embodiment of FIG. 6, it is shown that the adjustment voltage VH is also applied to the word line WL22 rather than to the adjacent initialization cell. However, the disclosure is not limited thereto. For example, in an embodiment, when the plurality of word lines that are not connected to the target memory cell 85 are individually driven, a ground voltage GND may be applied to the word line WL22. The ground voltage GND may be applied to a plurality of bit lines (e.g., BL12) that are not connected to the target memory cell 85.

In the present disclosure, a “positive polarity” and a “negative polarity” are based on the polarity of a voltage applied to each of a bit line and a word line during a read operation. If a polarity of a voltage applied to each of a bit line and a word line is the same as the polarity of the voltage applied to each of the bit line and the word line during the read operation, the polarity of the voltage is the positive polarity. In the opposite case, the polarity of the voltage is the negative polarity.

In the initialization operation performed on a memory cell, a difference VDD of two voltages applied to both ends of the memory cell may be greater than a voltage difference applied to both ends of the memory cell to write data to the memory cell and a voltage difference applied to both ends of the memory cell to read the data from the memory cell.

The adjustment voltage VH may be higher than the ground voltage GND and lower than the positive polarity voltage VDD/2. For example, the adjustment voltage VH may be set to a voltage within VDD/10 to VDD/5. Then, the voltage at both ends of the adjacent initialization cells 81 and 82 may decrease compared to a comparative example, and thus, the leakage current flowing through the adjacent initialization cells 81 and 82 may decrease. In a comparative example, when the ground voltage GND is applied to the plurality of word lines WL11 and WL12, the voltage at both ends of the adjacent initialization cells 81 and 82 is VDD/2-GND, however when the adjustment voltage VH is applied to the plurality of word lines WL11 and WL12, the voltage at both ends of the adjacent initialization cells 81 and 82 is VDD/2-VH. That is, the voltage at both ends of the adjacent initialization cells 81 and 82 may decrease by the adjustment voltage VH compared to a comparative example. Because the leakage current of a memory cell in the off condition tends to decrease as the voltage at both ends of a memory cell device decreases, the leakage current of the target memory cell 85 during the initialization operation may decrease due to the voltage at both ends of the adjacent initialization cells 81 and 82 decreased by the adjustment voltage VH. Then, the initialization operation of the target memory cell 85 may be stably performed such that the threshold voltage may decrease to the level suitable for the memory operation.

Compared to a case in which the ground voltage GND is applied to the plurality of word lines WL11 and WL12 in a comparative example, the adjustment voltage VH may be applied to the plurality of word lines WL11 and WL12 such that a voltage difference at both ends of the initialization memory cells 83 and 84 may increase. Then, the leakage current flowing through the initialization memory cells 83 and 84 may increase. When determining a level of the adjustment voltage VH, the amount of decrease in leakage current of the adjacent initialization cells and the amount of increase in leakage current of initialization memory cells other than the adjacent initialization cells among the initialization memory cells may be considered together by the adjustment voltage VH. For example, the adjustment voltage VH may be determined such that the sum of leakage currents decreased due to the decrease in the voltage at both ends of the adjacent initialization cells 81 and 82 is greater than the sum of leakage currents increased due to the increase in the voltage at both ends of the other initialization memory cells 83 and 84.

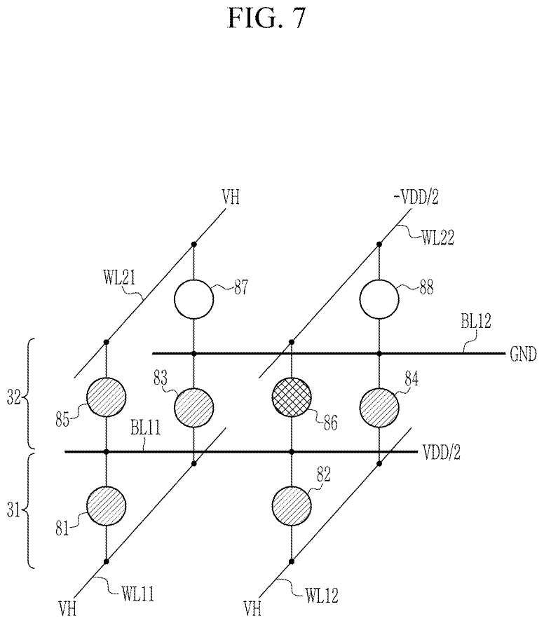

FIG. 7 is a diagram schematically illustrating a plurality of memory cells disposed in areas in which word lines and bit lines intersect according to an embodiment.

FIG. 7 shows a voltage application method when the memory cell 86 is a target memory cell following an initialization operation shown in FIG. 6.

In an initialization operation performed on the target memory cell 86, the positive polarity voltage VDD/2 may be applied to the bit line BL11, and the negative polarity voltage −VDD/2 may be applied to the word line WL22. The adjustment voltage VH may be applied to the plurality of word lines WL11, WL12, and WL21 connected to the adjacent initialization cells 81, 82, and 85 that share the bit line BL11 with the target memory cell 86. The ground voltage GND may be applied to the plurality of bit lines BL12 that are not connected to the target memory cell 86. The voltage at both ends of the adjacent initialization cells 81, 82, and 85 may decrease compared to a comparative example, and thus, the leakage current flowing in the adjacent initialization cells 81, 82, and 85 may decrease.

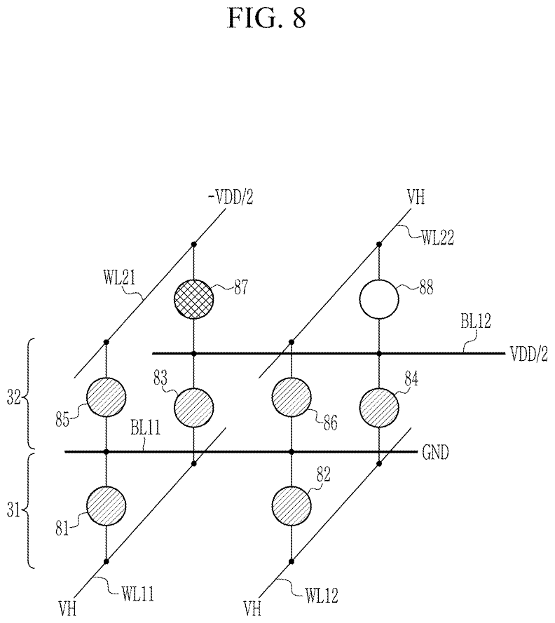

FIG. 8 is a diagram schematically illustrating a plurality of memory cells disposed in areas in which word lines and bit lines intersect according to an embodiment.

FIG. 8 shows a voltage application method when the memory cell 87 is a target memory cell after an initialization operation shown in FIG. 7.

In an initialization operation performed on the target memory cell 87, the positive polarity voltage VDD/2 may be applied to the bit line BL12, and the negative polarity voltage −VDD/2 may be applied to the word line WL21. The adjustment voltage VH may be applied to the plurality of word lines WL11 and WL12 connected to the adjacent initialization cells 83 and 84 that share the bit line BL12 with the target memory cell 87. The ground voltage GND may be applied to a plurality of bit lines (e.g., BL11) that are not connected to the target memory cell 87. The voltage at both ends of the adjacent initialization cells 83 and 84 may decrease compared to a comparative example, and thus, the leakage current flowing through the adjacent initialization cells 83 and 84 may decrease.

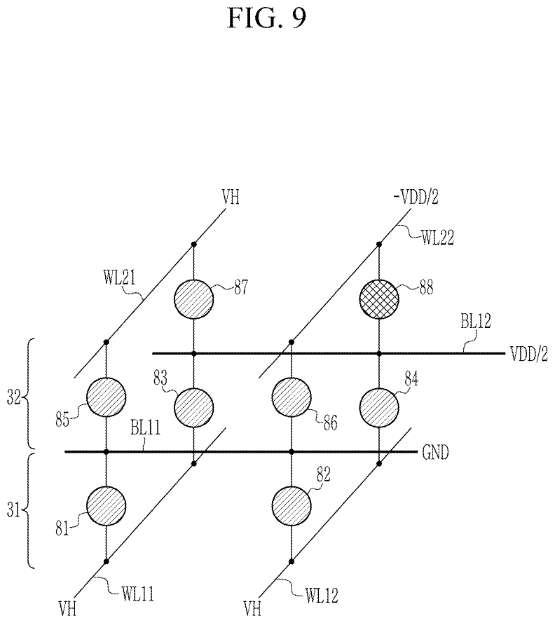

FIG. 9 is a diagram schematically illustrating a plurality of memory cells disposed in areas in which word lines and bit lines intersect according to an embodiment.

FIG. 9 shows a voltage application method when the memory cell 88 is a target memory cell following an initialization operation shown in FIG. 8.

In an initialization operation performed on the target memory cell 88, the positive polarity voltage VDD/2 may be applied to the bit line BL12, and the negative polarity voltage −VDD/2 may be applied to the word line WL22. The adjustment voltage VH may be applied to the plurality of word lines WL11, WL12, and WL21 connected to the adjacent initialization cells 83, 84, and 87 that share the bit line BL12 with the target memory cell 88. The ground voltage GND may be applied to the plurality of bit lines BL11 that are not connected to the target memory cell 88. The voltage at both ends of the adjacent initialization cells 83, 84, and 87 may decrease compared to a comparative example, and thus, the leakage current flowing in the adjacent initialization cells 83, 84, and 87 may decrease.

A method of applying the adjustment voltage VH is not limited to the methods shown in FIGS. 6 to 9. For example, an embodiment shown in FIG. 6 shows that, in a first memory layer and a second memory layer that share a bit line, the adjustment voltage VH is applied to word lines of initialized memory cells of the first memory layer. Alternatively, in the second memory layer and a third memory layer that share a word line, the adjustment voltage VH may be applied to bit lines of initialized memory cells of the second memory layer.

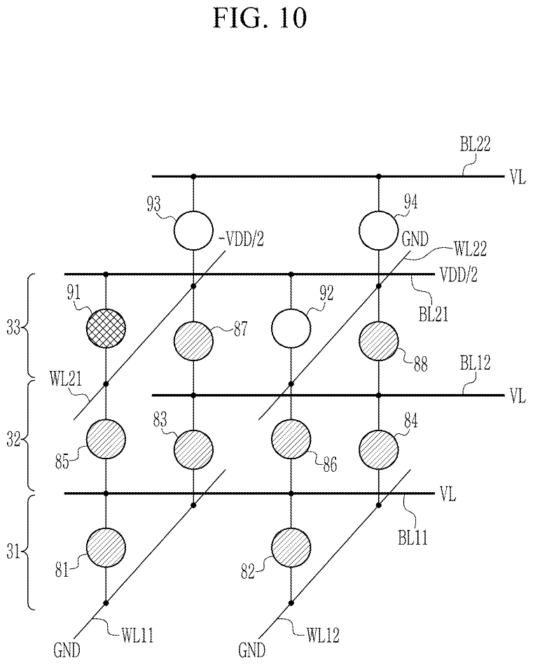

FIG. 10 is a diagram schematically illustrating a plurality of memory cells disposed in areas in which word lines and bit lines intersect according to an embodiment.

For convenience of explanation, FIG. 10 shows twelve memory cells 81 to 88 and 91 to 94 connected to the four bit lines BL11, BL12, BL21, and BL22 and the four word lines WL11, WL12, WL21, and WL22 among a plurality of bit lines and a plurality of word lines connected to the first to third memory layers 31 to 33.

In FIG. 10, the plurality of memory cells 81 to 88 disposed in the first memory layer 31 and the second memory layer 32 are initialized cells. That is, the threshold voltage of the plurality of memory cells 81 to 88 is lowered to a level suitable for a memory operation. Following initialization on the first memory layer 31 and the second memory layer 32, an initialization operation may be performed on the memory cell 91 disposed in the third memory layer 33. In the initialization operation performed on the target memory cell 91, the positive polarity voltage VDD/2 may be applied to the bit line BL21, and the negative polarity voltage −VDD/2 may be applied to the word line WL21. An adjustment voltage VL may be applied to a plurality of bit lines (e.g., BL11 and BL12) connected to adjacent initialization cells (e.g., 85 and 87) that share the word line WL21 with the target memory cell 91. The adjustment voltage VL may be applied to the bit line BL22 that is not connected to the adjacent initialization cells. Alternatively, the ground voltage GND may be applied to the bit line BL22. The ground voltage GND may be applied to the plurality of word lines WL11, WL12, and WL22 that are not connected to the target memory cell 91.

The adjustment voltage VL is a negative voltage and may have the same level as the adjustment voltage VH and have only the opposite polarity. That is, the adjustment voltage VL may be lower than the ground voltage GND and higher than the negative voltage −VDD/2. For example, the adjustment voltage VL may be set to a voltage within −VDD/5 to −VDD/10. Then, the voltage at both ends of the adjacent initialization cells 85 and 87 may decrease compared to a comparative example, and thus, the leakage current flowing through the adjacent initialization cells 85 and 87 may decrease. When the ground voltage GND of a comparative example is applied to the plurality of bit lines BL11 and BL12, the voltage at both ends of the adjacent initialization cells 85 and 87 is −VDD/2-GND, and when the adjustment voltage VL is applied to the plurality of bit lines BL11 and BL12, the voltage at both ends of the adjacent initialization cells 85 and 87 is −VDD/2-VL. That is, the voltage at both ends of the adjacent initialization cells 85 and 87 may decrease by the adjustment voltage VL compared to a comparative example. Because the leakage current of a memory cell in the off condition tends to decrease as the voltage at both ends of a memory cell device decreases, the leakage current of the target memory cell 91 during the initialization operation may decrease due to the voltage at both ends of the adjacent initialization cells 85 and 87 decreased by the adjustment voltage VL. Then, the initialization operation of the target memory cell 91 may be stably performed such that the threshold voltage may decrease to the level suitable for the memory operation.

Compared to a case in which the ground voltage GND is applied to the plurality of bit lines BL11 and BL12 in a comparative example, the adjustment voltage VL may be applied to the plurality of bit lines BL11 and BL12 such that a voltage difference at both ends of the initialization memory cells 86 and 88 and the memory cells 81 to 84 of the first memory layer 31 may increase. Then, the leakage current flowing through the initialization memory cells 86 and 88 and the memory cells 81 to 84 of the first memory layer 31 may increase. When determining a level of the adjustment voltage VL, the amount of decrease in leakage current of the adjacent initialization cells and the amount of increase in leakage current of initialization memory cells other than the adjacent initialization cells among the initialization memory cells may be considered together by the adjustment voltage VL. For example, the adjustment voltage VL may be determined such that the sum of leakage currents decreased due to the decrease in the voltage at both ends of the adjacent initialization cells 85 and 87 is greater than the sum of leakage currents increased due to the increase in the voltage at both ends of the other initialization memory cells 86 and 88 and the memory cells 81 to 84 of the first memory layer 31.

To suppress the increase in leakage current of the initialization memory cells other than the adjacent initialization cells 85 and 87 due to the adjustment voltage VL, the adjustment voltage VL may be applied to the plurality of word lines WL11 and WL12 of FIG. 10.

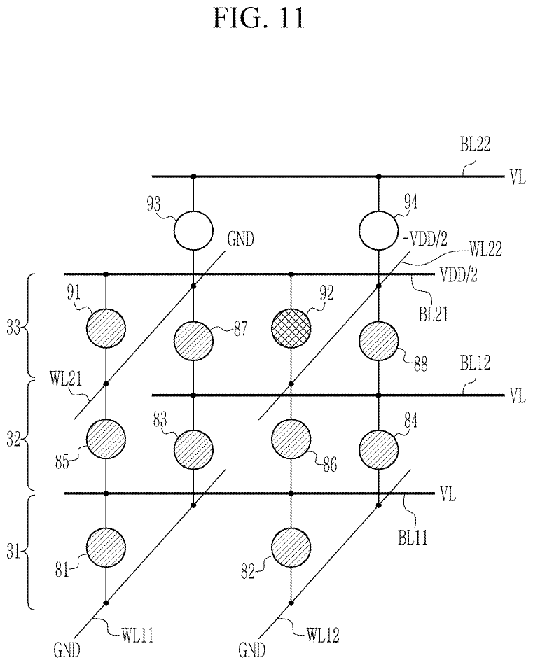

FIG. 11 is a diagram schematically illustrating a plurality of memory cells disposed in areas in which word lines and bit lines intersect according to an embodiment.

FIG. 11 shows a voltage application method when the memory cell 92 is a target memory cell following an initialization operation shown in FIG. 10.

In an initialization operation performed on the target memory cell 92, the positive polarity voltage VDD/2 may be applied to the bit line BL21, the negative polarity voltage −VDD/2 may be applied to the word line WL22, and the ground voltage GND may be applied to the word lines WL21, WL11, and WL12. The adjustment voltage VL may be applied to the plurality of bit lines BL11 and BL12 connected to the adjacent initialization cells 86 and 88 that share the word line WL22 with the target memory cell 92. The adjustment voltage VL may be applied to the plurality of bit lines BL22 that are not connected to the target memory cell 92. The voltage at both ends of the adjacent initialization cells 86 and 88 may decrease compared to a comparative example, and thus, the leakage current flowing through the adjacent initialization cells 86 and 88 may decrease.

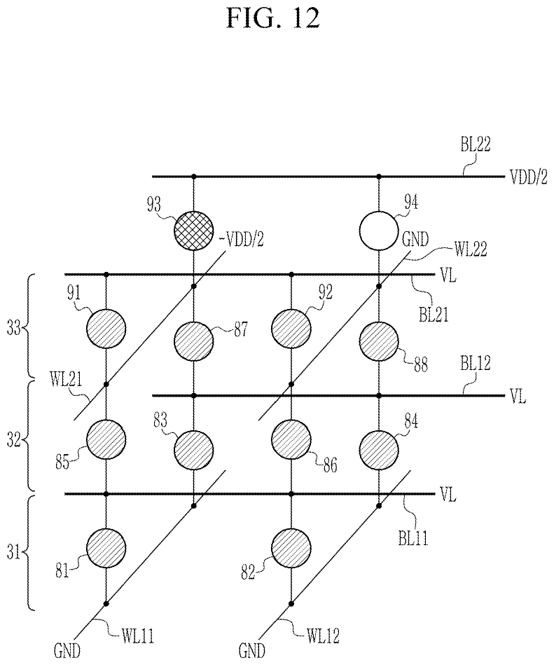

FIG. 12 is a diagram schematically illustrating a plurality of memory cells disposed in areas in which word lines and bit lines intersect according to an embodiment.

FIG. 12 shows a voltage application method when the memory cell 93 is a target memory cell after an initialization operation shown in FIG. 11.

In an initialization operation performed on the target memory cell 93, the positive polarity voltage VDD/2 may be applied to the bit line BL22, the negative polarity voltage −VDD/2 may be applied to the word line WL21, and the ground voltage GND may be applied to the word lines WL22, WL11, and WL12. The adjustment voltage VL may be applied to the plurality of bit lines BL11, BL12, and BL21 connected to the adjacent initialization cells 91, 85 and 87 that share the word line WL21 with the target memory cell 93. The voltage at both ends of the adjacent initialization cells 91, 85 and 87 may decrease compared to a comparative example, and thus, the leakage current flowing through the adjacent initialization cells 91, 85 and 87 may decrease.

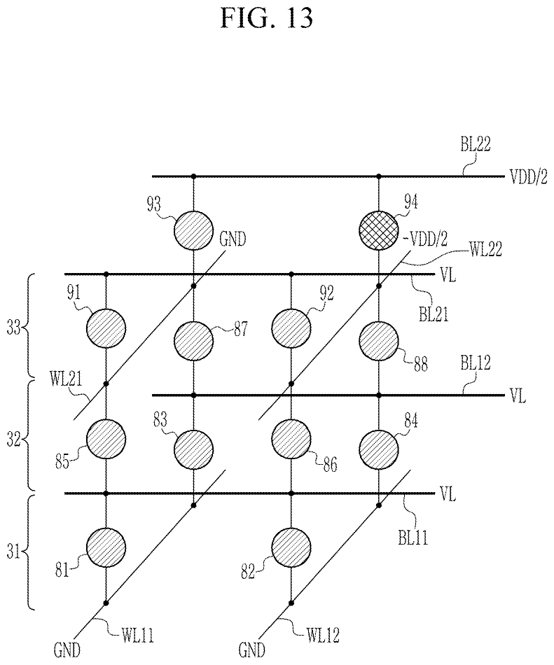

FIG. 13 is a diagram schematically illustrating a plurality of memory cells disposed in areas in which word lines and bit lines intersect according to an embodiment.

FIG. 13 shows a voltage application method when the memory cell 94 is a target memory cell following an initialization operation shown in FIG. 12.

In an initialization operation performed on the target memory cell 94, the positive polarity voltage VDD/2 may be applied to the bit line BL21, the negative polarity voltage −VDD/2 may be applied to the word line WL22, and the ground voltage GND may be applied to the word lines WL21, WL11, and WL12. The adjustment voltage VL may be applied to the plurality of bit lines BL11, BL12, and BL21 connected to the adjacent initialization cells 86, 88, and 92 that share the word line WL22 with the target memory cell 94. The voltage at both ends of the adjacent initialization cells 86, 88, and 92 may decrease compared to a comparative example, and thus, the leakage current flowing through the adjacent initialization cells 86, 88, and 92 may decrease.

A method of reducing the leakage current of an adjacent initialization cell by using the adjustment voltage VH or the adjustment voltage VL may be modified in various ways. For example, in an embodiment shown in FIG. 11, the memory cell 91 that shares the bit line BL21 with the target memory cell 92 may be an adjacent initialization cell.

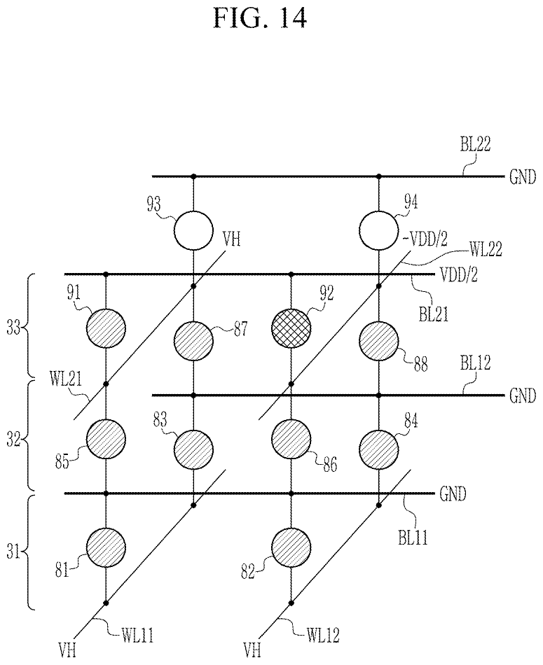

FIG. 14 is a diagram schematically illustrating a plurality of memory cells disposed in areas in which word lines and bit lines intersect according to an embodiment.

In the initialization operation performed on the target memory cell 92, the positive polarity voltage VDD/2 may be applied to the bit line BL21, and the negative polarity voltage −VDD/2 may be applied to the word line WL22. The adjustment voltage VH may be applied to a plurality of word lines (e.g., WL21) connected to adjacent initialization cells (e.g., 91) that share the bit line BL21 with the target memory cell 92. The ground voltage GND may be applied to the plurality of bit lines BL11, BL12, and BL22 that are not connected to the target memory cell 92. The voltage at both ends of the adjacent initialization cell 91 may decrease compared to a comparative example, and thus, the leakage current flowing in the adjacent initialization cell 91 may decrease.

FIG. 14 shows that the adjustment voltage VH is applied to the word lines WL11 and WL12, but the disclosure is not limited thereto. For example, in an embodiment, the ground voltage GND may be applied to the word lines WL11 and WL12.

FIGS. 6 to 14 show embodiments in which an adjustment voltage is supplied during an initialization operation when a plurality of memory layers constituting the memory cell array 30 includes an initialized memory layer. Corresponding embodiments may be applied to the initialization operation on memory cells on which the initialization operation is performed at a lower priority under the condition that the memory cells on which the initialization operation has been completed are present. That is, the adjustment voltage may be applied to the initialization operation on memory cells at various locations where the initialization operation may fail due to an increase in the leakage current of the initialized memory cells. For example, the adjustment voltage may be used in the initialization operation performed on the memory cells away from a location by a certain address in the memory cell array 30. A location may correspond to a point where a voltage is supplied to a bit line.

During the initialization operation, the leakage current may increase farther away from the point (hereinafter, referred to as a reference point) where the voltage is supplied to the bit line. As the memory cell is farther away from the reference point, the number of leakage paths between the corresponding memory cell and the reference point increases, and thus, there is a high probability that initialization of the memory cell located farther away from the reference point fails. Considering this, the adjustment voltage may be used in the initialization operation performed on memory cells located far away from the reference point.

However, the disclosure is not limited thereto. For example, in an embodiment, an initialization progress direction may be determined in consideration of the increase in leakage current according to the progress of the initialization operation. For example, the initialization progress direction may be determined from a memory cell farthest from the reference point to a memory cell closest to the reference point.

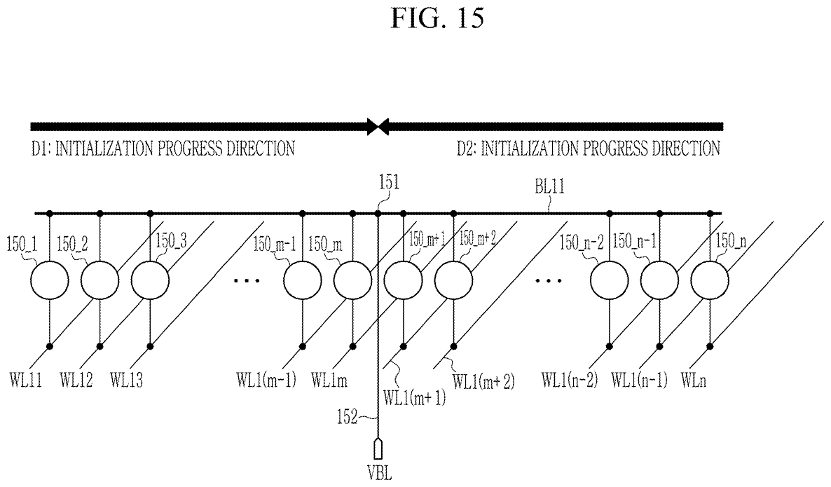

FIG. 15 is a diagram schematically illustrating a plurality of memory cells and a plurality of word lines connected to a bit line for describing an embodiment.

As shown in FIG. 15, the bit line BL11 may be connected to a wiring 152 at a reference point 151, and a bit line voltage VBL may be supplied through the wiring 152. The wiring 152 may be connected to a wiring that supplies the bit line voltage VBL in the peripheral circuit 40.

After an initialization operation is performed on memory cells 150_1 to 150_m located on the left in FIG. 15 based on the reference point 151, the initialization operation may be performed on memory cells 150_m+1 to 150_n located on the right in FIG. 15 based on the reference point 151, and alternatively, vice versa.

According to an initialization progress direction D1, initialization operations with respect to the memory cells 150_1 to 150_m may proceed in the order from the memory cell 150_1 located farthest from the reference point 151 to the memory cell 150_m located closest thereto. In addition, according to an initialization progress direction D2, initialization operations with respect to the memory cells 150_m+1 to 150_n may proceed in the order from the memory cell 150_n located farthest from the reference point 151 to the memory cell 150_m+1 located closest thereto.

The number of initialization memory cells increases according to an initialization progress direction, but a location of a target memory cell is closer to the reference point than the initialization memory cells, and thus, the influence of leakage current flowing through the initialization memory cells on the initialization operation of the target memory cell may be reduced.

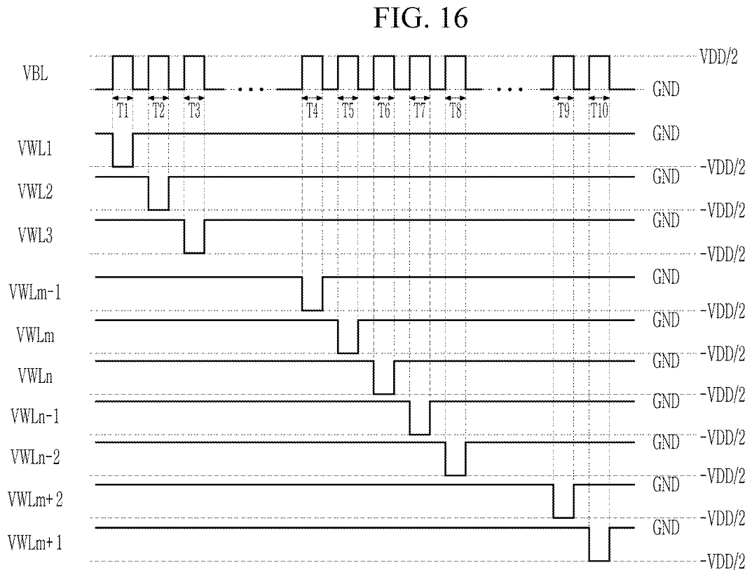

FIG. 16 is a waveform diagram illustrating voltage waveforms supplied to a bit line and a plurality of word lines during an initialization operation according to an initialization progress direction shown in FIG. 15.

FIG. 16 shows the waveforms of a bit line voltage VBL provided to the bit line BL11 and word line voltages VWL1 to VWLn provided to the word lines WL11 to WL1n.

The bit line voltage VBL may be toggled between the positive polarity voltage VDD/2 and the ground voltage GND. Each of a plurality of word line voltages VWLi may include a pulse of the negative polarity voltage −VDD/2 (i is one of positive integers from 1 to n). In each of periods T1 to T10 in which the bit line voltage VBL is VDD/2, the negative polarity voltage −VDD/2 may be applied to the corresponding word line among the plurality of word lines WL11 to WL1n. For example, in the period T1, the word line voltage VWL1, which is the negative polarity voltage −VDD/2, may be applied to the word line WL11, in the period T2, the word line voltage VWL2, which is the negative polarity voltage −VDD/2, may be applied to the word line WL12, in the period T3, the word line voltage VWL3, which is the negative polarity voltage −VDD/2, may be applied to the word line WL13, in the period T4, the word line voltage VWLm−1, which is the negative polarity voltage −VDD/2, may be applied to the word line WL1(m−1), and in the period T5, the word line voltage VWLm, which is the negative polarity voltage −VDD/2, may be applied to the word line WL1m. Subsequently, in the period T6, the word line voltage VWLn, which is the negative polarity voltage −VDD/2, may be applied to the word line WL1n, in the period T7, the word line voltage VWLn−1, which is the negative polarity voltage −VDD/2, may be applied to the word line WL1 (n−1), in the period T8, the word line voltage VWLn−2, which is the negative polarity voltage −VDD/2, may be applied to the word line WL1 (n−2), in the period T9, the word line voltage VWLm+2, which is the negative polarity voltage −VDD/2, may be applied to the word line WL1(m+2), and in the period T10, the word line voltage VWLm+1, which is the negative polarity voltage −VDD/2, may be applied to the word line WL1(m+1).

As shown in FIGS. 15 and 16, in an embodiment, with respect to each bit line, a voltage difference VDD between the bit line voltage VBL and the word line voltage VWLi may occur, in the order from a memory cell farthest from a reference point 151 to a memory cell closest to the reference point 151, and a target memory cell may be initialized.

A method of limiting leakage current during the initialization operation is not limited to the embodiments described above. For example, in an embodiment, the leakage current may be limited by adjusting the polarity of a reset operation. The polarity of the initialization operation may be defined based on the voltage of a bit line and the voltage of a word line applied during a read operation on a memory cell. For example, when a positive polarity voltage is applied to the bit line and a negative polarity voltage is applied to the word line during the read operation, an operation of applying the positive polarity voltage to the bit line and applying the negative polarity voltage to the word line during the initialization operation may be defined as a positive polarity initialization operation, and in the opposite case, the operation may be defined as a negative polarity initialization operation. When positive polarity initialization is performed on the target memory cell, the target memory cell is initialized to a set state. When negative polarity initialization is performed on the target memory cell, the target memory cell is initialized to a reset state. A memory cell initialized in the set state may be referred to as a set initialization memory cell, and a memory cell initialized in the reset state may be referred to as a reset initialization memory cell. When the positive polarity initialization operation is performed on the target memory cell, the leakage current when an already initialized memory cell is the reset initialization memory cell is relatively less than the leakage current when the already initialized memory cell is the set initialization memory cell. This is because when voltages for the positive polarity initialization operation are applied to the bit line and the word line with respect to the target memory cell, the resistance of the reset initialization memory cell that shares the bit line or the word line with the target memory cell is greater than the resistance of the set initialization memory cell that shares the bit line or the word line with the target memory cell. This is due to a phenomenon in which in the operating characteristics of a selector only memory (SOM) device, such as the resistive memory cell of embodiments of the present disclosure, the resistance of the SOM device increases and the threshold voltage increases when a voltage of the opposite polarity to a voltage polarity applied to the SOM device is applied to the SOM device at the time of a previous turn-on operation.

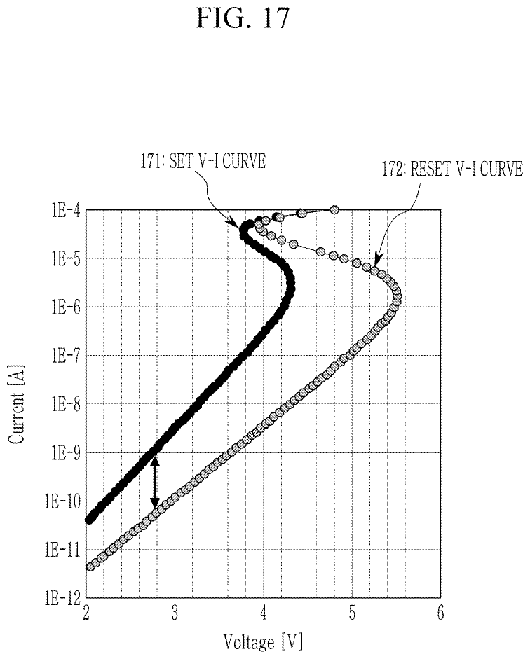

FIG. 17 is a curved graph illustrating voltage-current characteristics in a positive polarity write and voltage-current characteristics in a negative polarity write with respect to a SOM device.

In FIG. 17, a horizontal axis represents a voltage difference applied to both ends of the SOM device, and a vertical axis represents a current flowing in the SOM device. An S-shaped behavior on a V-I curve shown in FIG. 17 shows the snap-back characteristics of an OTS. The voltage applied to the SOM device increases until reaching the threshold voltage, and when the SOM device is turned on beyond the threshold voltage, the voltage that maintains the SOM device in an on state decreases. For example, in a reset V-I curve with respect to the SOM device, when the voltage applied to the SOM device is about 5.5 V, the SOM device is turned on and the resistance of the SOM device in the on state decreases due to snap-back, and when the voltage applied to the SOM device is about 4 V or higher, the SOM device remains in the on state. When the voltage applied to the SOM device is lower than about 4 V, the SOM device may be turned off.

In FIG. 17, a set V-I curve 171 indicates a current when applying a voltage to the SOM device with a bit line voltage and a word line voltage of the same polarity as the polarity of each of the bit line voltage and the word line voltage during a read operation, and conversely, a reset V-I curve 172 indicates a current when applying a voltage to the SOM device. The set V-I curve 171 may represent V-I characteristics in a positive polarity initialization operation, and the reset V-I curve 172 may represent V-I characteristics in a negative polarity initialization operation.

As shown in FIG. 17, at a voltage of about 3 V when the SOM device is in an off state, the leakage current in the reset V-I curve 172 is less than the leakage current in the set V-I curve 171. Based on this, even in the initialization operation, the leakage current of the reset initialization memory cell on which the negative polarity initialization operation has been performed is less than the leakage current of the set initialization memory cell on which the positive initialization operation has been performed.

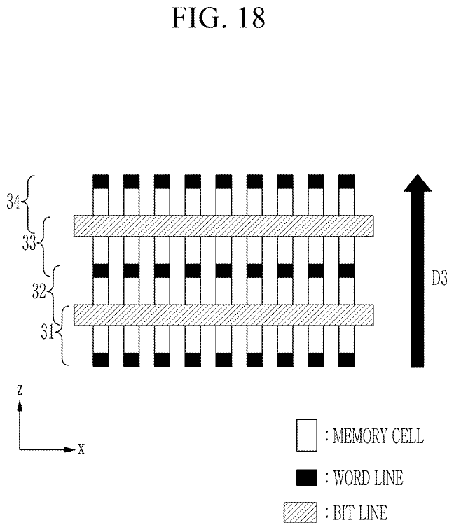

FIG. 18 is a diagram schematically illustrating that positive/negative polarity initialization operations are performed according to an initialization progress direction during an initialization operation in a multi-deck structure according to an embodiment.

A memory cell array shown in FIG. 18 schematically shows a cross section of the memory cell array 30 shown in FIG. 1 cut along an xz plane.

As shown in FIG. 18, a progress direction D3 of the initialization operation with respect to the first to fourth memory layers 31 to 34 may be the first memory layer 31, the second memory layer 32, the third memory layer 33, and a fourth memory layer 34. Then, the positive polarity initialization operation may be performed on each of a plurality of memory cells of the first memory layer 31, and subsequently the negative polarity initialization operation may be performed. Next, the positive polarity initialization operation may be performed on each of a plurality of memory cells of the second memory layer 32, and subsequently, the negative polarity initialization operation may be performed. At this time, when the positive polarity initialization operation is performed on the memory cells of the second memory layer 32, the memory cells of the first memory layer 31 are reset initialization memory cells. Therefore, compared to a comparative example, the amount of leakage current that occurs during the positive polarity initialization operation on the memory cells of the second memory layer 32 may be reduced. Next, the positive polarity initialization operation may be performed on each of a plurality of memory cells of the third memory layer 33, and subsequently, the negative polarity initialization operation may be performed. At this time, when the positive polarity initialization operation is performed on the memory cells of the third memory layer 33, the memory cells of the first memory layer 31 and the second memory layer 32 are reset initialization memory cells. Therefore, the amount of leakage current that occurs during the positive polarity initialization operation on the memory cells of the third memory layer 33 may be reduced compared to a comparative example. Finally, the positive polarity initialization operation may be performed on each of a plurality of memory cells of the fourth memory layer 34, and subsequently, the negative polarity initialization operation may be performed. At this time, when the positive polarity initialization operation is performed on the memory cells of the fourth memory layer 34, the memory cells of the first to third memory layers 31 to 33 are reset initialization memory cells. Therefore, the amount of leakage current that occurs during the positive polarity initialization operation on the memory cells of the fourth memory layer 34 may be reduced compared to a comparative example.

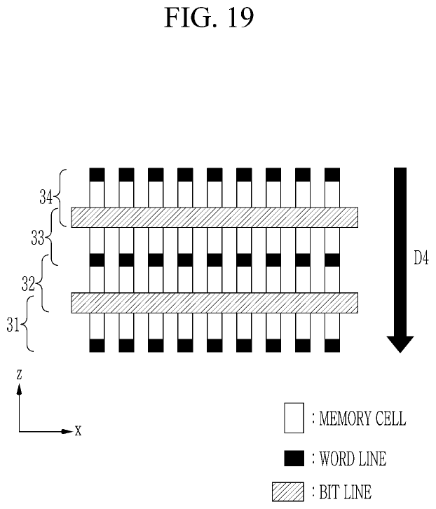

FIG. 19 is a diagram schematically illustrating that positive/negative polarity initialization operations are performed according to an initialization progress direction during an initialization operation in a multi-deck structure according to an embodiment. In an embodiment shown in FIG. 19, a progress direction D4 of the initialization operation with respect to the first to fourth memory layers 31 to 34 may be the fourth memory layer 34, the third memory layer 33, the second memory layer 32, and the first memory layer 31. The initialization progress direction in an embodiment of FIG. 19 is opposite to that in an embodiment of FIG. 18. An embodiment of FIG. 19 is the same as an embodiment of FIG. 18 in that the positive polarity initialization operation is followed by the negative polarity initialization operation on each of a plurality of memory cells in each memory layer.

With respect to the plurality of memory cells within the memory layer, the positive polarity initialization operation and the negative polarity initialization operation may be sequentially performed according to the initialization progress direction within the corresponding memory layer.

Referring again to FIG. 15, unlike the initialization progress direction mentioned in an embodiment of FIG. 15, the initialization operation may be performed in the order from the memory cell 150_1 to the memory cell 150_n or vice versa. At this time, the positive polarity initialization operation and the negative polarity initialization operation may be sequentially performed on each of the memory cells 150_1 to 150_n.

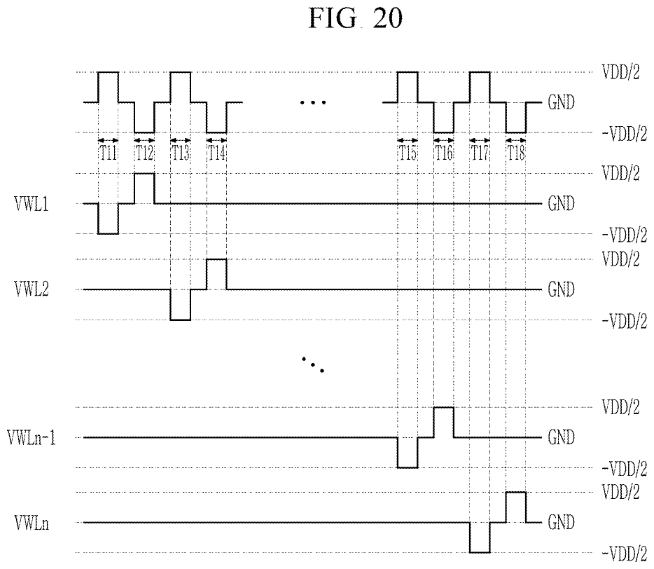

FIG. 20 is a waveform diagram illustrating waveforms of a bit line voltage and a word line voltage for a positive polarity initialization operation or a negative polarity initialization operation supplied to a bit line and a plurality of word lines according to an embodiment.

FIG. 20 shows the waveforms of the bit line voltage VBL provided to the bit line BL11 and the word line voltages VWL1 to VWLn provided to the word lines WL11 to WL1n.

In a period T11, the bit line voltage VBL is the positive polarity voltage VDD/2, and the word line voltage VWL1 is the negative polarity voltage −VDD/2. Then, the positive polarity initialization operation on the memory cell 150_1 is performed. Subsequently, in a period T12, the bit line voltage VBL is the negative polarity voltage-VDD/2, and the word line voltage VWL1 is the positive polarity voltage VDD/2. Then, the negative polarity initialization operation on the memory cell 150_1 is performed.

Next, in a period T13, the bit line voltage VBL is the positive polarity voltage VDD/2, and the word line voltage VWL2 is the negative polarity voltage −VDD/2. Then, the positive polarity initialization operation on the memory cell 150_2 is performed. Then, in a period T14, the bit line voltage VBL is the negative polarity voltage −VDD/2, and the word line voltage VWL2 is the positive polarity voltage VDD/2. Then, the negative polarity initialization operation on the memory cell 150_2 is performed.

In the same way, the positive polarity initialization operation and the negative polarity initialization operation on the memory cell 150_n−1 may be performed in periods T15 and T16, and the positive polarity initialization operation and the negative polarity initialization operation on the memory cell 150_n may be performed in periods T17 and T18.

As such, the positive polarity initialization operation and the negative polarity initialization operation on the plurality of memory cells 150_1 to 150_n are sequentially performed. However, the disclosure is not limited thereto. For example, in an embodiment, when the initialization operation is performed in a direction from a memory cell farthest from a reference point to a memory cell closest to the reference point, as in an embodiment shown in FIG. 15, the positive polarity initialization operation and the negative polarity initialization operation may be performed in initialization progress directions (e.g., D1 and D2).

In previously described embodiments, all of a plurality of memory cells constituting one memory layer may be implemented as reset initialization memory cells through the positive polarity initialization operation and the negative polarity initialization operation. However, the disclosure is not limited thereto. For example, in an embodiment, the negative polarity initialization operation may be performed on a plurality of first memory cells that are earlier in an initialization progress order among the plurality of memory cells constituting the memory layer, and only the positive polarity initialization operation may be performed on a plurality of remaining second memory cells among the plurality of memory cells. A ratio of the plurality of first memory cells among all the plurality of memory cells may vary depending on the design. For example, when the ratio is about 0.5, when following an initialization progress direction in one memory layer, the half of all memory cells on which the initialization operation is first performed may be the reset initialization memory cells, and the other half may be the set initialization memory cells.

Referring again to FIG. 15, when the initialization progress direction is D1, the negative polarity initialization operation may be performed on a plurality of memory cells (e.g., 150_1, 150_2, and 150_3) located above a specific address value from the reference point 151, and the positive polarity initialization operation may be performed on a plurality of memory cells (e.g., 150_m−1 and 150_m) located within a specific address value. Subsequently, when the initialization progress direction is D2, the negative polarity initialization operation may be performed on a plurality of memory cells (e.g., 150_n−2, 150_n−1, and 150_n) located above a specific address value from the reference point 151, and the positive polarity initialization operation may be performed on a plurality of memory cells (e.g., 150_m+1 and 150_m+2) located within a specific address value. An “address” may indicate a location of each of a plurality of word lines arranged in the x-axis direction in FIG. 1.

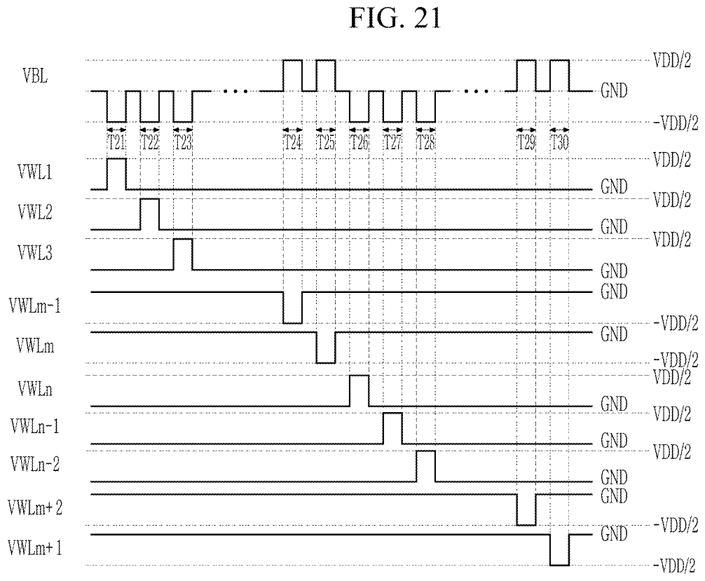

FIG. 21 is a waveform diagram illustrating waveforms of a bit line voltage and a word line voltage for a positive polarity initialization operation or a negative polarity initialization operation supplied to a bit line and a plurality of word lines according to an embodiment.

FIG. 21 shows the waveforms of the bit line voltage VBL provided to the bit line BL11 and the word line voltages VWL1 to VWLn provided to the word lines WL11 to WL1n. In an embodiment, the negative polarity initialization operation may be performed on memory cells 150_1 to 150_(n/4) with addresses less than n/4 among addresses n, and memory cells 150_(3n/4) to 150_n with addresses greater than 3n/4 among all the addresses n. The positive polarity initialization operation may be performed on the remaining memory cells. For convenience of explanation, the addresses of the memory cells 150_1 to 150_3 shown in FIG. 15 are less than n/4, the addresses of the memory cells 150_n−2 to 150_n are greater than 3n/4, and the addresses of the memory cells 150_m−1, 150_m, 150_m+1, and 150_m+2 may be greater than n/4 and less than 3n/4.

First, in the initialization progress direction D1 of FIG. 15, in each of periods T21, T22, and T23, the bit line voltage VBL, which is the negative polarity voltage −VDD/2, may be applied to the bit line BL11, and the word line voltages VWL1, VWL2, and VWL3, which are the positive polarity voltages VDD/2, may be respectively applied to the word lines WL11, WL12, and WL13. Then, each of the memory cells 150_1, 150_2, and 150_3 may be a reset initialization memory cell by the negative polarity initialization operation in each of the periods T21, T22, and T23. Thereafter, in each of periods T24 and T25, the bit line voltage VBL, which is the positive polarity voltage VDD/2, may be applied to the bit line BL11, and the word line voltages VWLm−1 and VWLm, which are the negative polarity voltages −VDD/2, may be respectively applied to the word lines WL1(m−1) and WL1m. Then, each of the memory cells 150_m−1 and 150_m may be the set initialization memory cell by the positive polarity initialization operation in each of the periods T24 and T25. When the positive polarity initialization operation is performed, first initialized memory cells include a reset initialization memory cell, and thus, leakage current may be reduced compared to a comparative example in which the first initialized memory cells include a set initialization memory cell.

Next, in the initialization progress direction D2 of FIG. 15, in each of periods T26, T27, and T28, the bit line voltage VBL, which is the negative polarity voltage −VDD/2, may be applied to the bit line BL11, and the word line voltages VWLn, VWLn−1, and VWLn−2, which are the positive polarity voltages VDD/2, may be respectively applied to the word lines WL1n, WL1 (n−1), and WL1 (n−2). Then, each of the memory cells 150_n, 150_n−1, and 150_n−2 may be a reset initialization memory cell by the negative polarity initialization operation in each of the periods T26, T27, and T28. Thereafter, in each of periods T29 and T30, the bit line voltage VBL, which is the positive polarity voltage VDD/2, may be applied to the bit line BL11, and, the word line voltages VWLm+2 and VWLm+1, which are the negative polarity voltages −VDD/2, may be respectively applied to the word lines WL1(m+2) and WL1(m+1). Then, each of the memory cells 150_m+2 and 150_m+1 may be a set initialization memory cell by the positive polarity initialization operation in each of the periods T29 and T30. When the positive polarity initialization operation is performed, first initialized memory cells include a reset initialization memory cell, and thus, leakage current may be reduced compared to a comparative example in which the first initialized memory cells include a set initialization memory cell.

Even in the initialization progress direction different from an embodiment of FIG. 21, the negative polarity initialization operation may be performed on a certain percentage of memory cells on which the initialization operation is first performed among a plurality of memory cells constituting one memory layer, and the positive polarity initialization operation may be performed on the remaining memory cells.

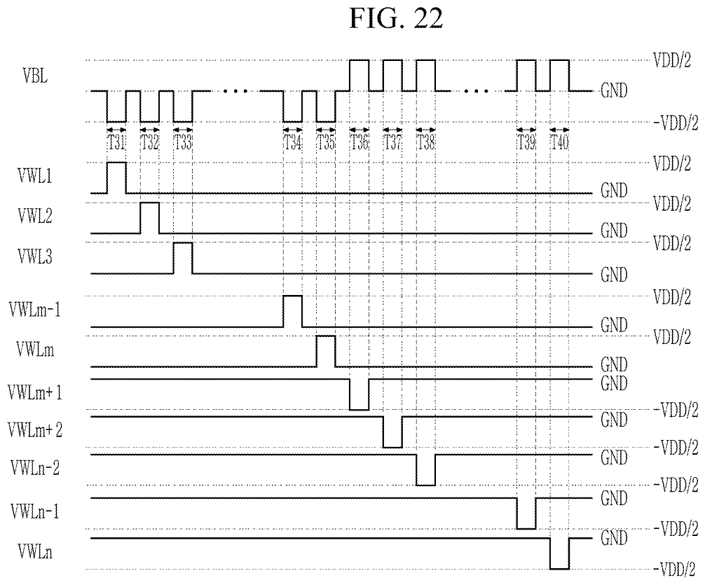

FIG. 22 is a waveform diagram illustrating waveforms of a bit line voltage and a word line voltage for a positive polarity initialization operation or a negative polarity initialization operation supplied to a bit line and a plurality of word lines according to an embodiment.

An embodiment of FIG. 22 relates to the waveform diagram when initialization progresses in a direction from the memory cell 150_1 to the memory cell 150_n, unlike an embodiment of FIG. 21. The negative polarity initialization operation may be performed from the memory cell 150_1 to the memory cell 150_m, and the positive polarity initialization operation may be performed from the memory cell 150_m+1 to the memory cell 150_n.

In each of periods T31, T32, T33, T34, and T35, the bit line voltage VBL, which is the negative polarity voltage −VDD/2, may be applied to the bit line BL11, and the word line voltages VWL1, VWL2, VWL3, VWLm−1, and VWLm which are the positive polarity voltages VDD/2, may be respectively applied to the word lines WL11, WL12, WL13, WL1(m−1), and WL1m. Then, each of the memory cells 150_1, 150_2, 150_3, 150_m−1, and 150_m may be a reset initialization memory cell by the negative polarity initialization operation in each of the periods T31, T32, T33, T34, and T35.

Next, in each of periods T36, T37, T38, T39, and T40, the bit line voltage VBL, which is the positive polarity voltage VDD/2, may be applied to the bit line BL11, and the word line voltages VWLm+1, VWLm+2, VWLn−2, VWLn−1, and VWLn, which are the negative polarity voltages −VDD/2, may be respectively applied to the word lines WL1(m+1), WL1(m+2), WL1 (n−2), WL1 (n−1), and WL1n. Then, each of the memory cells 150_m+1, 150_m+2, 150_n−2, 150_n−1, and 150_n may be a set initialization memory cell by the positive polarity initialization operation in each of the periods T36, T37, T38, T39, and T40. When the positive polarity initialization operation is performed, first initialized memory cells include a reset initialization memory cell, and thus, leakage current may be reduced compared to a comparative example in which the first initialized memory cells include a set initialization memory cell.

In an embodiment of FIG. 6, the initialization operation on a plurality of memory cells of the first memory layer 31 may be implemented through embodiments of FIGS. 15, 16, 20, 21, and 22. In addition, in the initialization operation after the second memory layer 32, the positive polarity initialization operation and/or the negative polarity initialization operation may be applied to embodiments in which the adjustment voltages VH and VL are used.

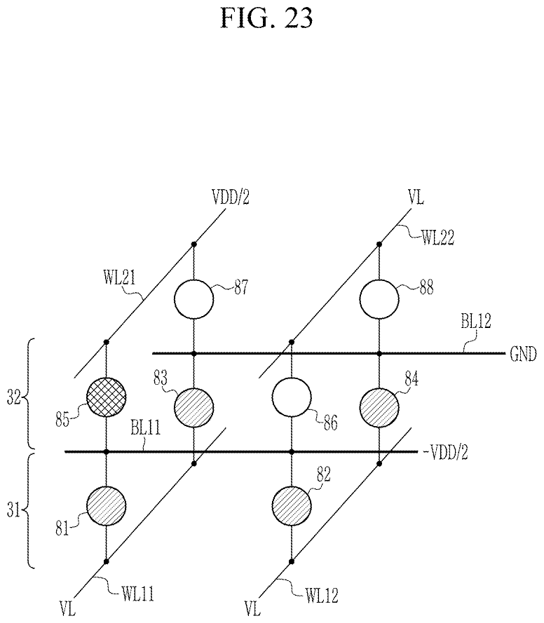

FIG. 23 is a diagram schematically showing a plurality of memory cells disposed in areas in which word lines and bit lines intersect according to an embodiment.

An embodiment of FIG. 6 corresponds to a positive polarity initialization operation. An embodiment of FIG. 23 relates to a negative polarity initialization operation performed on the target memory cell 85. FIG. 23 shows voltages applied to the two bit lines BL11 and BL12 and the four word lines WL11, WL12, WL21, and WL22. The positive polarity initialization operation shown in FIG. 6 may be followed by the negative polarity initialization operation shown in FIG. 23. Alternatively, the positive polarity initialization operation shown in FIG. 6 may be performed, or the negative polarity initialization operation shown in FIG. 23 may be performed according to an address of a memory cell.

In a negative polarity initialization operation performed on the target memory cell 85, the negative polarity voltage −VDD/2 may be applied to the bit line BL11, and the positive polarity voltage VDD/2 may be applied to the word line WL21. The adjustment voltage VL may be applied to a plurality of word lines (e.g., WL11 and WL12) connected to adjacent initialization cells (e.g., 81 and 82) that share the bit line BL11 with the target memory cell 85. One voltage may be applied to a plurality of word lines that are not connected to the target memory cell 85. In an embodiment of FIG. 23, it is shown that the adjustment voltage VL is also applied to the word line WL22 that is not connected to the adjacent initialization cell. However, the disclosure is not limited thereto. For example, in an embodiment when the plurality of word lines that are not connected to the target memory cell 85 are individually driven, the ground voltage GND may be applied to the word line WL22. The ground voltage GND may be applied to a plurality of bit lines (e.g., BL12) that are not connected to the target memory cell 85.

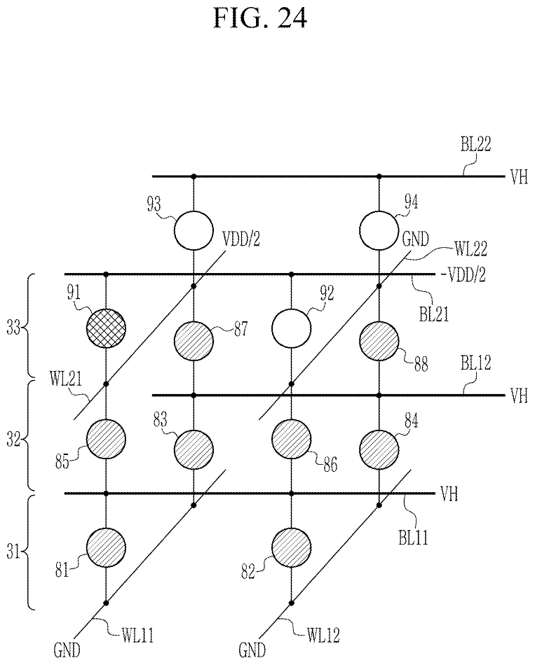

FIG. 24 is a diagram schematically showing a plurality of memory cells disposed in areas in which word lines and bit lines intersect according to an embodiment.

An embodiment of FIG. 10 corresponds to a positive polarity initialization operation. An embodiment of FIG. 24 relates to a negative polarity initialization operation on the target memory cell 91. FIG. 24 shows voltages applied to the twelve memory cells 81 to 88 and 91 to 94 connected to the four bit lines BL11, BL12, BL21, and BL22 and the four word lines WL11, WL12, WL21, and WL22. The positive polarity initialization operation shown in FIG. 10 may be followed by the negative polarity initialization operation shown in FIG. 24. Alternatively, the positive polarity initialization operation shown in FIG. 10 may be performed, or the negative polarity initialization operation shown in FIG. 24 may be performed according to an address of a memory cell.

In a negative polarity initialization operation performed on the target memory cell 91, the negative polarity voltage −VDD/2 may be applied to the bit line BL21, and the positive polarity voltage VDD/2 may be applied to the word line WL21. The adjustment voltage VH may be applied to a plurality of bit lines (e.g., BL11 and BL12) connected to adjacent initialization cells (e.g., 85 and 87) that share the bit line BL21 with the target memory cell 91. One voltage may be applied to a plurality of bit lines that are not connected to the target memory cell 91. In an embodiment of FIG. 24, it is shown that the adjustment voltage VH is also applied to the bit line BL22 that is not connected to the adjacent initialization cell. However, the disclosure is not limited thereto. For example, in an embodiment, when the plurality of bit lines that are not connected to the target memory cell 91 are individually driven, the ground voltage GND may be applied to the bit line BL22. The ground voltage GND may be applied to a plurality of word lines (e.g., WL11, WL12, and WL22) that are not connected to the target memory cell 91.

As such, the adjustment voltages VH and VL may be applied to a word line or a bit line connected to an adjacent initialization cell according to the positive polarity initialization operation and the negative polarity initialization operation.

Embodiments described above may be applied to each of a plurality of memory cell arrays on a wafer. However, the disclosure is not limited thereto. For example, embodiments may also be applied to a package including a memory cell array, a memory device including the memory cell array, etc.

A semiconductor device including a memory device including a memory cell array and a memory controller that controls the memory device are described below.

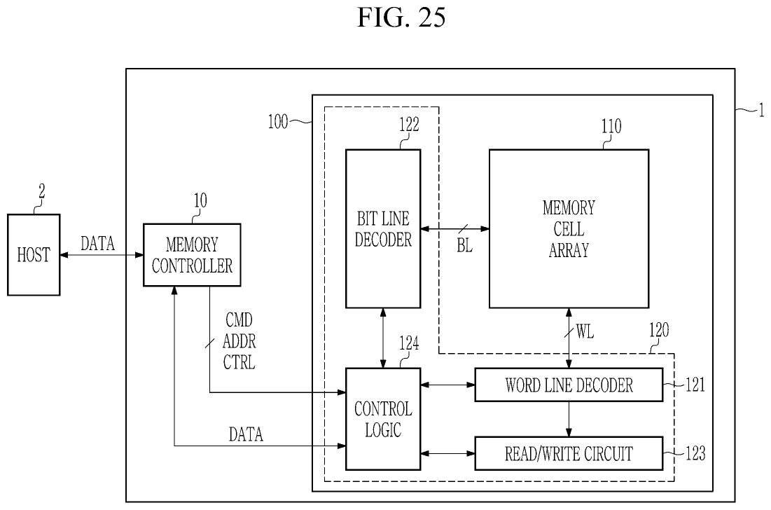

FIG. 25 is a block diagram illustrating a semiconductor device 1 according to an embodiment.

Referring to FIG. 25, the semiconductor device 1 includes a memory controller 10 and a memory device 100, and the memory device 100 may include a memory cell array 110 and a peripheral circuit 120. The peripheral circuit 120 may include decoder circuits 121 and 122, a read/write circuit 123, a control logic 124, etc. The memory cell array 110 may be implemented in the same way as the memory cell array 30 shown in FIG. 1.

The memory controller 10 may generate an address ADDR, a command CMD, and a control signal CTRL according to a request from a host 2, and provide the same to the memory device 100. The memory controller 10 may generate the address ADDR, the command CMD, and the control signal CTRL according to a read request, a write request, an initialization request, etc. from the host 2. The memory device 100 may perform write (or program), read, and initialization operations according to the address ADDR, the command CMD, and the control signal CTRL. The memory controller 10 may transmit data DATA to be written to the memory device 100, or receive the data DATA read from the memory device 100, and provide the same to the host 2.

The decoder circuits 121 and 122 may include a word line decoder 121 connected to a plurality of memory cells through word lines WL and a bit line decoder 122 connected to the plurality of memory cells through bit lines BL. The control logic 124 may control operations of the word line decoder 121, the bit line decoder 122, and the read/write circuit 123 according to the address ADDR, the command CMD, and the control signal CTRL. According to the control of the control logic 124, the read/write circuit 123 may record data in at least one memory cell specified by the word line decoder 121 and the bit line decoder 122, and read the data from the at least one specified memory cell.

When the control logic 124 receives the command CMD instructing an initialization operation, the control logic 124 may perform the initialization operation on a plurality of memory cells of the memory cell array 130 through the word line decoder 121 and the bit line decoder 122. In the initialization operation, according to the control of the control logic 124, the bit line decoder 122 may select one of the positive polarity voltage VDD/2, the negative polarity voltage −VDD/2, the adjustment voltages VH and VL, and the ground voltage GND and apply the selected voltage to each of the plurality of bit lines BL, and the word line decoder 121 may select one of the positive polarity voltage VDD/2, the negative polarity voltage −VDD/2, the adjustment voltages VH and VL, and the ground voltage GND and apply the selected voltage to each of the plurality of word lines WL. The timing at which the word line decoder 121 and the bit line decoder 122 respectively apply the selected voltage to the plurality of word lines WL and the plurality of bit lines BL may be controlled by the control logic 124. The initialization operations controlled by the control logic 124 may be the same as previously described embodiments.

While the present disclosure has been particularly shown and described with reference to embodiments thereof, it will be understood by those of ordinary skill in the art that various changes in form and detail may be made therein without departing from the spirit and scope of the present invention as defined by the following claims.

What is claimed is:

1. A memory device, comprising:
a plurality of word lines extending in a first direction;
a plurality of bit lines extending in a second direction crossing the first direction;
a plurality of memory cells disposed in a plurality of areas in which the plurality of word lines and the plurality of bit lines intersect; and
a circuit configured to apply a first voltage to a first bit line of a target memory cell, which is an initialization target cell among the plurality of memory cells, apply a second voltage to a first word line of the target memory cell, and perform at least one of a first operation and a second operation,
wherein the plurality of bit lines includes the first bit line, and the plurality of word lines includes the first word line,
wherein the first operation includes applying an adjustment voltage to a second bit line or a second word line connected to an adjacent initialized memory cell that is an initialized memory cell among adjacent initialization cells that share the first bit line or the first word line,
wherein the second operation includes applying a third voltage of an opposite polarity to the first voltage to a third bit line of a next target memory cell that is initialized after initialization of the target memory cell, and applying a fourth voltage of an opposite polarity to the second voltage to a third word line of the next target memory cell, and
wherein the plurality of bit lines includes the second bit line and the third bit line, and the plurality of word lines includes the second word line and the third word line.

2. The memory device of claim 1, wherein:
in the first operation, the target memory cell and the adjacent initialized memory cell share the first bit line, and the adjustment voltage is applied to the second word line connected to the adjacent initialized memory cell.

3. The memory device of claim 2, wherein:
a voltage difference between the first voltage and the adjustment voltage is less than a voltage difference between the first voltage and a ground voltage.

4. The memory device of claim 2, wherein:
when the third voltage having a polarity opposite to the first voltage is applied to the first bit line following the first voltage, and the fourth voltage having a polarity opposite to the second voltage is applied to the first word line following the second voltage,
in the first operation, a different adjustment voltage having a polarity opposite to the adjustment voltage is applied to the second word line.

5. The memory device of claim 1, wherein:
in the first operation, the target memory cell and the adjacent initialized memory cell share the first word line, and the adjustment voltage is applied to the second bit line connected to the adjacent initialized memory cell.

6. The memory device of claim 5, wherein:
a voltage difference between the second voltage and the adjustment voltage is less than a voltage difference between the second voltage and a ground voltage.

7. The memory device of claim 5, wherein:
when the third voltage having a polarity opposite to the first voltage is applied to the first bit line following the first voltage, and the fourth voltage having a polarity opposite to the second voltage is applied to the first word line following the second voltage,
in the first operation, a different adjustment voltage having a polarity opposite to the adjustment voltage is applied to the second bit line.

8. The memory device of claim 1, wherein:
an initialization operation is performed in a first direction from a memory cell among the plurality of memory cells of an address farthest in one side direction from a reference point where a voltage is applied to the first bit line toward the reference point.

9. The memory device of claim 1, wherein:
the plurality of memory cells is implemented with a plurality of memory layers, and
with respect to the plurality of memory layers, an initialization operation is performed in a first direction from a lowest first layer to a highest second layer among the plurality of memory layers or in a second direction from the second layer to the first layer.

10. The memory device of claim 1, wherein:
in the second operation, the first voltage is a negative polarity voltage, the second voltage is a positive polarity voltage, the third voltage is a positive polarity voltage at a same level as the first voltage, and the fourth voltage is a negative polarity voltage at a same level as the second voltage, and
a positive polarity is the same as a polarity of a read voltage applied to a bit line among the plurality of bit lines or a word line among the plurality of word lines when reading a memory cell among the plurality of memory cells, and a negative polarity is opposite to the polarity of the read voltage.

11. The memory device of claim 10, wherein:
the first voltage is applied to the third bit line following the third voltage, and the second voltage is applied to the third word line following the fourth voltage.

12. The memory device of claim 10, wherein:
the third bit line is the same as the first bit line, and
when an initialization operation is performed in a direction from a memory cell among the plurality of memory cells with an address farthest from a reference point where a voltage is applied to the first bit line to the reference point, a distance between the target memory cell and the reference point where the voltage is applied to the first bit line is closer than a distance between the next target memory cell and the reference point.

13. The memory device of claim 10, wherein:
the third bit line is the same as the first bit line, and
when an initialization operation is performed from one end of the first bit line to another end of the first bit line, the target memory cell is disposed in an area between the one end of the first bit line and a reference point based on the reference point where a voltage is applied to the first bit line, and the next target memory cell is disposed in an area between the other end of the first bit line and the reference point.

14. An initializing method of a memory device including a plurality of word lines, a plurality of bit lines, and a plurality of memory cells disposed in a plurality of areas in which the plurality of word lines and the plurality of bit lines intersect, the initializing method comprising:
applying a first voltage to a first bit line of a target memory cell, which is an initialization target cell among the plurality of memory cells, and applying a second voltage to a first word line of the target memory cell,
wherein the plurality of bit lines includes the first bit line, and the plurality of word lines includes the first word line; and
applying an adjustment voltage to a second bit line or a second word line connected to an adjacent initialized memory cell that is an initialized memory cell among adjacent initialization cells that share the first bit line or the first word line,
wherein the plurality of bit lines includes the second bit line, and the plurality of word lines includes the second word line.

15. The initializing method of claim 14, wherein:
applying the adjustment voltage includes, when the target memory cell and the adjacent initialized memory cell share the first bit line, applying the adjustment voltage to the second word line connected to the adjacent initialized memory cell.

16. The initializing method of claim 15, further comprising:
applying a third voltage having a polarity opposite to the first voltage to the first bit line following the first voltage, and applying a fourth voltage having a polarity opposite to the second voltage to the first word line following the second voltage; and
applying a different adjustment voltage having a polarity opposite to the adjustment voltage to the second word line.

17. The initializing method of claim 14, wherein:
applying the adjustment voltage includes, when the target memory cell and the adjacent initialized memory cell share the first word line, applying the adjustment voltage to the second bit line connected to the adjacent initialized memory cell.

18. The initializing method of claim 17, further comprising:
applying a third voltage having a polarity opposite to the first voltage to the first bit line following the first voltage, and applying a fourth voltage having a polarity opposite to the second voltage to the first word line following the second voltage; and
applying a different adjustment voltage having a polarity opposite to the adjustment voltage to the second bit line.

19. An initializing method of a memory device including a plurality of word lines, a plurality of bit lines, and a plurality of memory cells disposed in a plurality of areas in which the plurality of word lines and the plurality of bit lines intersect, the initializing method comprising:
applying a first voltage to a first bit line of a target memory cell, which is an initialization target cell among the plurality of memory cells, and applying a second voltage to a first word line of the target memory cell,
wherein the plurality of bit lines includes the first bit line, and the plurality of word lines includes the first word line; and
applying a third voltage of an opposite polarity to the first voltage to a second bit line of a next target memory cell that is initialized after initialization of the target memory cell, and applying a fourth voltage of an opposite polarity to the second voltage to a second word line of the next target memory cell,
wherein the plurality of bit lines includes the second bit line, and the plurality of word lines includes the second word line.

20. The initializing method of claim 19, wherein:
the first voltage is a negative polarity voltage, the second voltage is a positive polarity voltage, the third voltage is a positive polarity voltage at a same level as the first voltage, and the fourth voltage is a negative polarity voltage at a same level as the second voltage, and
a positive polarity is the same as a polarity of a read voltage applied to a bit line among the plurality of bit lines or a word line among the plurality of word lines when reading a memory cell among the plurality of memory cells, and a negative polarity is opposite to the polarity of the read voltage.
